(19) United States
(12) Patent Application Publication
(10) Pub. No.: US 2005/0253190 A1
(43) Pub. Date: Nov. 17, 2005

(54) Semiconductor device

(75) Inventors: Hideki Okumura, Hyogo (JP); Mitsuhiko Kitagawa, Tokyo (JP); Takuma Hara, Kanagawa (JP); Takayoshi Ino, Hyogo (JP); Kiyotaka Arai, Hyogo (JP); Satoshi Taji, Hyogo (JP); Masanobu Tsuchitani, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/101,570

(22) Filed: Apr. 8, 2005

(30) Foreign Application Priority Data
Apr. 9, 2004 (JP) 2004-115163

(51) Int. Cl. H01L 29/94

(52) U.S. Cl. 257/330

(57) ABSTRACT

A semiconductor device comprises a semiconductor substrate; a semiconductor layer provided on the surface of the semiconductor substrate; a base layer provided on the surface of the semiconductor layer; a source layer provided on the surface of the base layer; a trench formed to pass through the source layer, the base layer, and the semiconductor layer from the surface of the source layer, and reaching the semiconductor substrate; a gate electrode provided from the source layer to at least the semiconductor layer within the trench; and an insulator provided between the gate electrode and the base layer so as to fill in the inside of the trench below the gate electrode, the insulator insulating the gate electrode from the base layer, and generating a potential distribution from the gate electrode toward the semiconductor substrate when a voltage is applied to the gate electrode.

### CROSS-REFERENCE TO RELATED APPLICATION

This application is based upon and claims the benefit of priority from the prior Japanese Patent Applications No. 2004-115163, filed on Apr. 9, 2004, the entire contents of which are incorporated herein by reference.

### BACKGROUND OF THE INVENTION

1. Field of the Invention

The present invention relates to a semiconductor device.

2. Background Art

Among relay devices switching high-frequency signals, there are mechanical relay devices and semiconductor relay devices. A conventional semiconductor relay device can controls a high-frequency signal of about a few hundred MHz, but cannot control a high-frequency signal exceeding a few GHz. This is because parasitic capacitances (a sum of these parasitic capacitances is called an output capacitance) are present between a gate and a drain and between a source and the drain of a MOSFET (metal-oxide semiconductor field-effect transistor) that is used in the semiconductor relay device. When this output capacitance is large, a high-frequency signal cannot be cut off even when the MOSFET is in an off state, and therefore, the semiconductor relay device cannot operate at a high speed. Consequently, the mechanical relay device is generally used to switch a high-frequency signal exceeding a few GHz.

For the MOSFET of the semiconductor relay device, it is important to decrease the on-resistance to decrease power loss. The on-resistance is explained with reference to FIG. 6. FIG. 6 shows a structure of a UMOS as a conventional MOSFET. As internal resistances of a UMOS, there are a substrate resistance, a drain drift resistance, a channel resistance, a contact resistance, a wiring resistance, and a wire resistance. Conventionally, in a low break-down voltage UMOS having 20 to 60 volts as break-down voltage, the channel resistance occupies about 50 to 60% of the total internal resistance. Therefore, a cell pitch Wp of a trench 50 is miniaturized to decrease the channel resistance. As a result, recently, in a low break-down voltage UMOS product, a resistance component of a drift layer 20 occupies 60% or more of the total internal resistance. Accordingly, in order to decrease the on-resistance, it is important to decrease the resistance of the drift layer 20.

As described above, in order to interrupt a high-frequency signal, it is desirable to decrease the output capacitance. Also, in order to decrease power loss, it is desirable to decrease the on-resistance. Therefore, when Cout×Ron (hereinafter, also referred to as “a CR product”) is low (where Ron denotes the on-resistance, and Cout denotes the output capacitance), this becomes an indicator showing that the performance of the MOSFET for a relay is excellent. However, since the on-resistance and the output capacitance are mutually in a tradeoff relationship, it is conventionally difficult to make the CR product smaller.

Further, the break-down voltage between the source and the drain of the MOSFET for a semiconductor relay is usually prescribed as a specification. Therefore, this break-down voltage must be maintained at a level equal to or above a prescribed value. In other words, it is required to make the CR product smaller while maintaining the break-down voltage between the source and the drain.

However, the output capacitance increases, when the concentration of impurity in the drift layer is increased to decrease the resistance of the drift layer. Further, the break-down voltage between the source and the drain is decreased, when the thickness of the drift layer is decreased to decrease the resistance of the drift layer (see FIG. 6).

When the cell pitch Wp of the trench is miniaturized, MOSFETs can be manufactured by a larger number in a certain area than that in other areas. Therefore, the on-resistance Ron becomes low. However, since the number of gates increases in this case, the capacitance between the gate and the drain becomes larger. Accordingly, the output capacitance Cout becomes large, and the CR product cannot be effectively made smaller as a result (see FIG. 6).

As explained above, it is conventionally difficult to make the CR product smaller while maintaining the break-down voltage between the source and the drain of the MOSFET.

### SUMMARY OF THE INVENTION

A semiconductor device according to an embodiment of the present embodiment comprises a semiconductor substrate; a semiconductor layer provided on the surface of the semiconductor substrate; a base layer provided on the surface of the semiconductor layer; a source layer provided on the surface of the base layer; a trench formed to pass through the source layer, the base layer, and the semiconductor layer from the surface of the source layer, and reaching the semiconductor substrate; a gate electrode provided from the source layer to at least the semiconductor layer within the trench; and an insulator provided between the gate electrode and the base layer so as to fill in the inside of the trench below the gate electrode, the insulator insulating the gate electrode from the base layer, and generating a potential distribution from the gate electrode toward the semiconductor substrate when a voltage is applied to the gate electrode.

A semiconductor device according to another embodiment of the present embodiment comprises a semiconductor substrate; a first semiconductor layer provided on the surface of the semiconductor substrate; a second semiconductor layer provided on the surface of the first semiconductor layer; a base layer provided on the surface of the second semiconductor layer; a source layer provided on the surface of the base layer; a trench formed to pass through the source layer, the base layer, the second semiconductor layer, and the first semiconductor layer from the surface of the source layer, and reaching the semiconductor substrate; a gate electrode provided from the source layer to at least the second semiconductor layer within the trench; and an insulator provided between the gate electrode and the base layer so as to fill in the inside of the trench below the gate electrode and insulating the gate electrode from the base layer.

A semiconductor device according to further embodiment of the present embodiment comprises a light-emitting element receiving an electrical signal, and outputting the electrical signal as an optical signal;
a photovoltaic generating element which receives an optical signal from the light-emitting element, and generates a direct-current voltage; and
a switching element including: a semiconductor substrate; a semiconductor layer provided on the surface of the semiconductor substrate; a base layer provided on the surface of the semiconductor layer; a source layer provided on the surface of the base layer; a trench formed to pass through the source layer, the base layer, and the semiconductor layer from the surface of the source layer, and reaching the semiconductor substrate; a gate electrode provided from the source layer to at least the semiconductor layer within the trench; and an insulator provided between the gate electrode and the base layer so as to fill in the inside of the trench below the gate electrode, the insulator insulating the gate electrode from the base layer, wherein
the switching element that switches the electrical signal flowing between the drain layer and the source layer, when the direct-current voltage from the photovoltaic generating element is applied to the gate electrode.

### BRIEF DESCRIPTION OF THE DRAWINGS

FIG. 1 is a cross-sectional view of a MOSFET 100 according to a first embodiment or a second embodiment of the present invention;

FIG. 2 is a cross-sectional view of a MOSFET 200 according to a third embodiment of the present invention;

FIG. 3 is a cross-sectional view of a MOSFET 300 according to a fourth embodiment of the present invention;

FIG. 4 is a table showing a result of carrying out a simulation of a comparison between the characteristics of the MOS 200 according to the present embodiment and the characteristics of the conventional MOS;

FIG. 5 is a circuit diagram of a photo relay 400 according to an embodiment of the present invention;

FIG. 6 shows a structure of a UMOS as a conventional MOSFET;

FIG. 7 is a table showing a relationship between a gate drive voltage and element characteristics of the FET 100 (20V series); and

FIG. 8 is a graph showing a relationship between a gate drive voltage and element characteristics of the FET 100 (20V series).

### DETAILED DESCRIPTION OF THE INVENTION

Exemplary embodiments of the present invention will be explained in detail below with reference to the accompanying drawings. The present invention is not limited by the embodiments.

A MOSFET according to the embodiments of the invention has a trench that passes through a base layer and a drift layer, and reaches a drain substrate. With this arrangement, the break-down voltage between a source and a drain of the MOSFET can be improved while maintaining the on-resistance and the output capacitance. Alternatively, the on-resistance of the MOSFET can be decreased while maintaining the break-down voltage and the output capacitance between the source and the drain. Further, an offset layer can be provided between a gate electrode and a drain layer while maintaining the break-down voltage and the on-resistance between the source and the drain. As a result, the output capacitance decreases, and the CR product can be effectively improved.

According to these embodiments, effects of the invention are not lost when an N-type semiconductor is changed to a P-type semiconductor, and when a P-type semiconductor is changed to an N-type semiconductor.

### First Embodiment

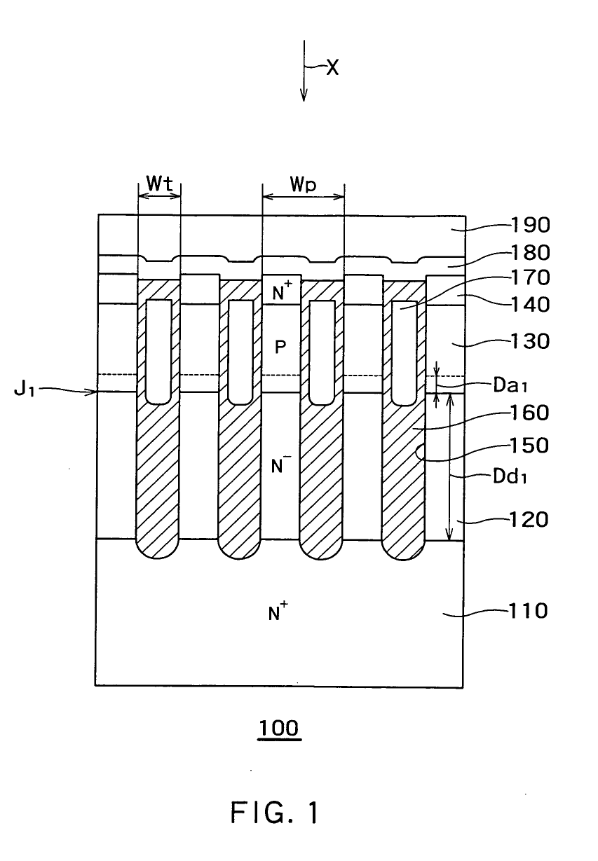

FIG. 1 is a cross-sectional view of a MOSFET (metal-oxide semiconductor field-effect transistor) 100 (hereinafter, simply referred to as “a MOS 100”) according to a first embodiment of the present invention. The MOS 100 includes an N⁺-type drain substrate 110, an N⁻-type drift layer 120, a P-type base layer 130, an N⁺-type source layer 140, a trench 150, an insulator 160, a gate electrode 170, an interlayer insulation film 180, and a source electrode 190.

The drift layer 120 is provided on the drain substrate 110. The base layer 130 is provided on the drift layer 120. The source layer 140 is formed at an upper part of the base layer 130. The trench 150 passes through the source layer 140, the base layer 130, and the drift layer 120 from the surface of the source layer 140, and reaches the drain substrate 110. Inside the trench 150, the gate electrode 170 extends from the height of the source layer 140 to the height of the drift layer 120 passing through the base layer 130. The height is a height from the surface of the drain substrate 110. The insulator 160 intervenes between the gate electrode 170 and the base layer 130. The insulator 160 works as a gate insulation film. Further, the insulator 160 is filled in the inside of the trench 150 below the gate electrode 170. In other words, the insulator 160 is filled within a part of the trench 150 adjacent to the drift layer 120.

The trench 150 is formed in a stripe shape or a mesh shape, when viewed from the top of the MOS 100 (i.e., in a direction of an arrow X in FIG. 1). Preferably, the insulator 160 is a dielectric like silicon dioxide (SiO₂).

A channel is generated in the base layer 130, by controlling the voltage of the gate electrode 170. As a result, a charge can be conducted between the source layer 140 and the drain substrate 110 by switching between the source layer 140 and the drain substrate 110. Since the insulator 160 is filled inside the trench below the gate electrode 170, a potential distribution is generated from the gate electrode 170 toward the drain substrate 110 inside the insulator 160, when a voltage is applied to the gate electrode 170.

Assume that Wt denotes a width of an opening of the trench 150 in the layout direction of the trench 150, and Wp denotes a sum of a distance between the trenches 150 adjacent in the layout direction and the opening width Wt (hereinafter, “a cell pitch”). Assume that Da1 denotes a width (or a length) of a depletion layer that extends from a junction J1 between the base layer 130 and the drift layer 120 toward the base layer 130, and Dd1 denotes a width (or a length) of a depletion layer that extends from the junction J1 toward the drift layer 120. Further, assume that Na denotes the concentration of impurity in the base layer 130, and Nd denotes the concentration of impurity in the drift layer 120. In this case, the following expression 1 is established because the amount of charge discharged from the depletion layer due to the depletion from the junction J1 to the drift layer 120 is equal to the amount of charge discharged from the depletion layer due to the depletion from the junction J1 to the base layer 130.
Na×(Wp−Wt)×Da1=Nd×(Wp−Wt)×Dd1 (Expression 1)

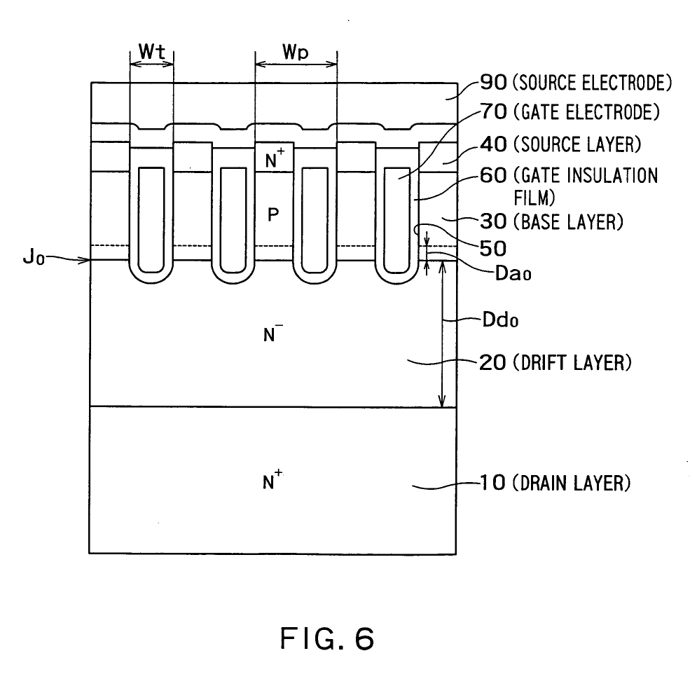

For convenience of explanation, assume that a conventional MOS shown in FIG. 6 is equal to the MOS 100 in constituent elements, except the trench and the insulator that is filled in the trench.

In the conventional MOS shown in FIG. 6, Da0 denotes a width (or a length) of a depletion layer that extends from a junction J0 between a base layer 30 and a drift layer 20 toward the base layer 30, and Dd0 denotes a width (or a length) of a depletion layer that extends from the junction J0 toward the drift layer 20. In this case, the following expression 2 is established because the amount of charge discharged from the depletion layer due to the depletion from the junction J0 to the drift layer 20 is equal to the amount of charge discharged from the depletion layer due to the depletion from the junction J0 to the base layer 30.
Na×(Wp−Wt)×Da0=Nd×Wp×Dd0 (Expression 2)

The configuration of a part from the junction J0 to the base layer 30 of the MOS shown in FIG. 6 is equal to the configuration of a part from the junction J1 to the base layer 130 of the MOS 100 shown in FIG. 1. Thus, Da0=Da1, therefore, the following expression 3 is derived from the expression 1 and the expression 2.
Nd×Wp×Dd0=Nd×(Wp−Wt)×Dd1 (Expression 3)

The expression 3 is simplified to derive the expression 4.
Dd1=(n/(n−1))Dd0, where n=Wp/Wt (Expression 4)

From the expression 4, it is clear that the depletion layer that extends to the drift layer in the MOS 100 extends by n/(n−1) times of the depletion layer of the MOS shown in FIG. 6, at the same voltage between the source and the drain. Since Wp>Wt, n>1. Therefore, Dd1>Dd0.

This means that the thickness of the drift layer 120 of the MOS 100 can be made larger than the thickness of the drift layer 20 of the conventional MOS, while maintaining the output capacitance. This is because even when the thickness of the drift layer 120 of the MOS 100 is increased, the capacitance between the source and the drain can be maintained due to the presence of the dielectric 160 within the drift layer 120.

When the thickness of the drift layer 120 is increased, the break-down voltage between the source and the drain of the MOS 100 becomes higher than the break-down voltage of the conventional MOS. In general, a power MOSFET such as a UMOS controls the break-down voltage between the source and the drain based on the thickness of the drift layer. For example, when n=2, the drift layer 120 can have a thickness two times larger than that of the drift layer 20 of the conventional MOS, and can have higher break-down voltage between the source and the drain along this increase in the thickness.

On the other hand, when the drift layer 120 of the MOS 100 has an increased thickness, the resistance of the drift layer 120 increases. However, according to the MOS 100, the trench 150 passes through the drift layer 120, and the dielectric 160 is filled in the trench 150. Therefore, when a voltage is applied to the gate electrode 170, a potential distribution is generated from the gate electrode 170 toward the drain substrate 110 inside the dielectric 160. When an absolute value of a gate drive voltage during the operation of the MOS 100 is increased, the potential distribution generated inside the dielectric 160 works on the carrier in the drift layer 120 near the dielectric 160. Consequently, the resistance of the drift layer 120 near the dielectric 160 can be decreased. In other words, even when the drift layer 120 of the MOS 100 has an increased thickness, the on-resistance can be maintained or decreased by increasing the absolute value of the gate drive voltage.

Therefore, the MOS 100 according to the present embodiment can increase the break-down voltage between the source and the drain while maintaining the on-resistance and the output capacitance.

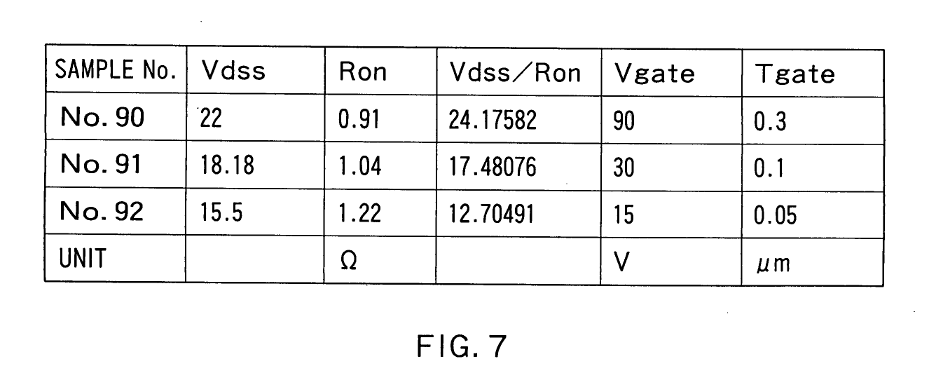

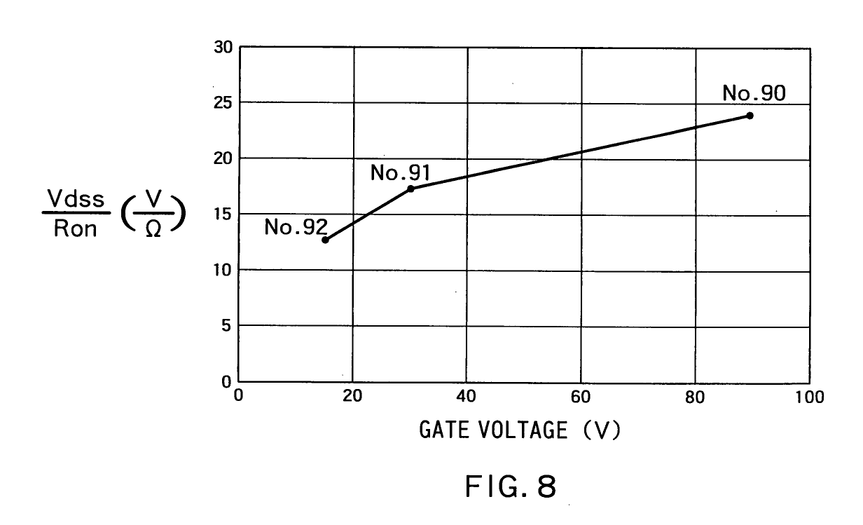

In the present embodiment, it is preferable that the gate drive voltage during the operation of the MOS 100 is substantially equal to or higher than the break-down voltage between the drain and the source. The reason for this is explained with reference to FIG. 7 and FIG. 8.

FIG. 7 and FIG. 8 are a table and a graph, respectively that show a relationship between a gate drive voltage and element characteristics of the FET 100 (20V series). In FIG. 8, the horizontal axis represents a gate drive voltage in an on state proportional to the thickness of a gate oxide film, and the vertical axis represents a value (Vdss/Ron) obtained by dividing an element break-down voltage (Vdss) by an on-resistance (Ron). The gate can be driven, for example, when the gate voltage is 30 volts per 0.1 micrometer of a gate oxide film as the gate drive voltage.

Sample numbers 90, 91, and 92 denote three samples of the MOS 100 that have the same device parameters except mutually different film thicknesses of the gate oxide film. It is preferable that the value of Vdss/Ron is larger when Cout is equal. As is clear from FIG. 7 and FIG. 8, when the thickness of the gate oxide film is increased and also when the gate drive voltage is increased, the element characteristics can be improved. When the gate drive voltage (Vgate) is set equal to or higher than the element break-down voltage (Vdss), the element characteristics (Vdss/Ron) can be improved. In other words, the value of Vdss/Ron becomes higher when the gate drive voltage (Vgate) becomes about one time, two times, and four times of the element break-down voltage (Vdss). In the first embodiment, the N⁻-type drift layer 120 shown in FIG. 1 can be replaced by the P⁻-type drift layer. In this case, the element becomes conductive due to an inversion layer generated in the P-type base layer 130 and the P⁻-type drift layer 120 according to the voltage applied to the gate electrode 170.

### Second Embodiment

In the first embodiment, it is assumed that the concentration of impurity in the drift layer 120 of the MOS 100 is equal to the concentration of impurity in the drift layer 20 of the conventional MOS shown in FIG. 6.

In a second embodiment, it is assumed that the width Dd1 of the depletion layer in the MOS 100 is equal to the width Dd0 of the depletion layer in the conventional MOS shown in FIG. 6 (that is, Dd1=Dd0), and that the concentration of impurity in the drift layer 20 is different from that in the drift layer 120. Other constituent elements according to the second embodiment are similar to those according to the first embodiment. Therefore, the second embodiment is explained with reference to FIG. 1.

When Dd1=Dd0 and when the concentration of impurity in the drift layer 120 is different from that in the drift layer 20, the expression 3 is substituted by the expression 5, where Nd1 denotes the concentration of impurity in the drift layer 120, and Nd0 denotes the concentration of impurity in the drift layer 20.
Nd0×Wp=Nd1×(Wp−Wt) (Expression 5)

This expression is simplified to derive the expression 6.
Nd1=(n/(n−1))Nd0, where n=Wp/Wt (Expression 6)

It is clear from the expression 6 that the concentration of impurity in the drift layer 120 of the MOS 100 is higher than that in the drift layer 20 of the MOS shown in FIG. 6 by n/(n−1) at the same voltage between the source and the drain. Since n>1, the concentration of impurity in the drift layer 120 of the MOS 100 is higher than that in the drift layer 20 of the conventional MOS. As a result, the resistance in the drift layer 120 of the MOS 100 is lower than the resistance in the drift layer 20 of the conventional MOS. When n=2, for example, the concentration of impurity in the drift layer 120 of the MOS 100 is higher than that in the drift layer 20 of the conventional MOS by two times.

On the other hand, since the thickness of the drift layer 20 is equal to that of the drift layer 120, the break-down voltage between the source and the drain is maintained. Further, even when the concentration of impurity in the drift layer 120 of the MOS 100 is set high, the output capacitance is maintained or can be decreased due to the presence of the dielectric 160 within the drift layer 120. When n=2, for example, the width Wt of the opening of the trench 150 is equal to the distance between adjacent trenches 150. Therefore, substantially a half of the volume of the drift layer 120 is occupied by the trench 150 (the insulator 160). Consequently, although the concentration of impurity in the drift layer 120 is high, the drift layer 120 can be easily depleted at a relatively low voltage between the source and the drain. As a result, the output capacitance is maintained or can be decreased.

As explained above, the MOS 100 according to the present embodiment can decrease the on-resistance while maintaining the break-down voltage between the source and the drain and the output capacitance.

### Third Embodiment

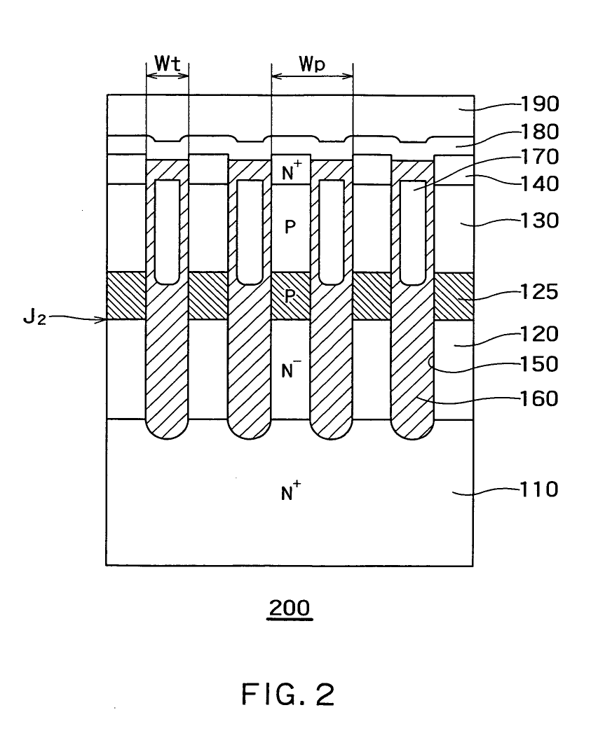

FIG. 2 is a cross-sectional view of a MOSFET 200 (hereinafter, simply referred to as “a MOS 200”) according to a third embodiment of the present invention. The MOS 200 is different from the MOS 100 shown in FIG. 1 in that the MOS 200 has a P-type offset layer 125 between the N⁻-type drift layer 120 and the P-type base layer 130. The concentration of impurity in the offset layer 125 can be the same as that in the base layer 130. Other constituent elements according to the present embodiment may be same as those according to the first embodiment. As described with reference to FIG. 7 and FIG. 8, it is preferable that the gate drive voltage during the operation of the MOS 200 is substantially equal to or higher than the break-down voltage between the drain and the source.

The trench 150 passes through the source layer 140, the base layer 130, the offset layer 125, and the drift layer 120, and reaches the drain substrate 110. The gate electrode 170 extends from the height of the source layer 140 to the height of the offset 125 passing through the base layer 130 within the trench 150, and does not reach the level of the drift layer 120.

Therefore, the offset layer 125 can decrease the capacitance between the gate and the drain, by expanding the distance between the gate electrode 170 and the drift layer 120. As a result, the output capacitance decreases.

On the other hand, since the gate electrode 170 does not reach the level of the drift layer 120, in order to maintain the on-resistance, the gate drive voltage during the operation of the MOS 200 is set higher than the gate drive voltage during the operation of the MOS 100. As a result, the dielectric 160 works on the carrier in the offset layer 125 near the dielectric 160 and the carrier in the drift layer 120. The concentration of impurity in the drift layer 120 can be set higher than that in the drift layer according to the conventional MOS, like in the first embodiment. Therefore, according to the third embodiment, the on-resistance can be maintained or can be decreased. Since the drift layer 120 has the same thickness as that of the drift layer 20, the break-down voltage between the source and the drain of the MOS 200 is equal to the break-down voltage between the source and the drain of the MOS 100.

Consequently, according to the present embodiment, the CR product can be effectively made smaller while maintaining the break-down voltage between the source and the drain. Further, the present embodiment has effects same as those of the first embodiment.

### Fourth Embodiment

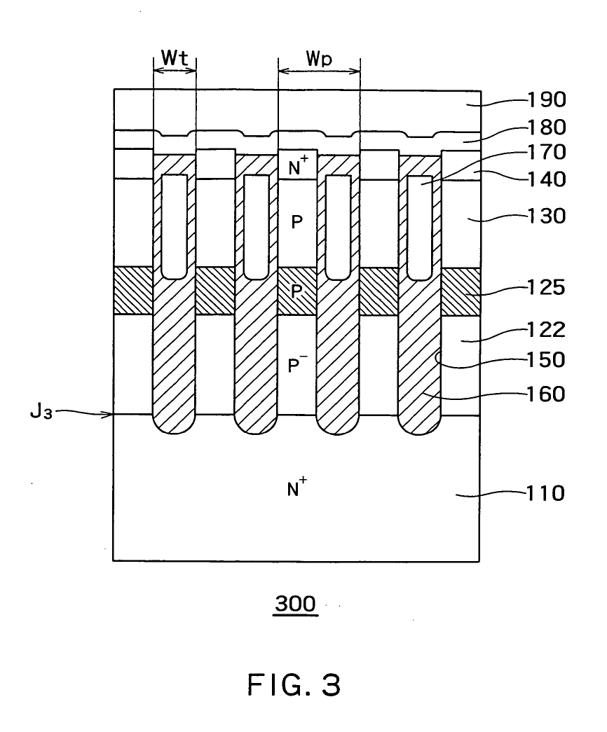

FIG. 3 is a cross-sectional view of a MOSFET 300 (hereinafter, simply referred to as “a MOS 300”) according to a fourth embodiment of the present invention. The fourth embodiment is different from the third embodiment in that a drift layer 122 is a P-type semiconductor. Other constituent elements according to the fourth embodiment are similar to those according to the third embodiment. It is preferable that the gate drive voltage during the operation of the MOS 300 is substantially equal to or higher than the break-down voltage between the drain and the source.

According to the fourth embodiment, the gate voltage is set relatively high, like in the third embodiment. Therefore, the dielectric 160 works on the carrier in the offset layer 125 near the dielectric 160 and on the carrier in the drift layer 122. Consequently, even when the drift layer 122 is of a P-type, a channel can be formed in the base layer 130, the offset layer 125, and the drift layer 120.

On the other hand, since the offset layer 125 and the drift layer 122 work as the offset layer between the gate electrode 170 and the drain substrate 110, the capacitance between the gate and the drain decreases more than that according to the third embodiment.

According to the fourth embodiment, the depletion layer extends from a junction J3 between the drain substrate 110 and the drift layer 122. However, since the concentration of impurity in the drain substrate 110 is higher than that in the drift layer 122, the depletion layer of the drain substrate 110 extends toward the drift layer 122. Therefore, the break-down voltage between the source and the drain can be maintained.

The MOS according to the fourth embodiment can decrease the output capacitance more than that according to the third embodiment while maintaining the break-down voltage between the source and the drain. Consequently, the CR product can be further improved.

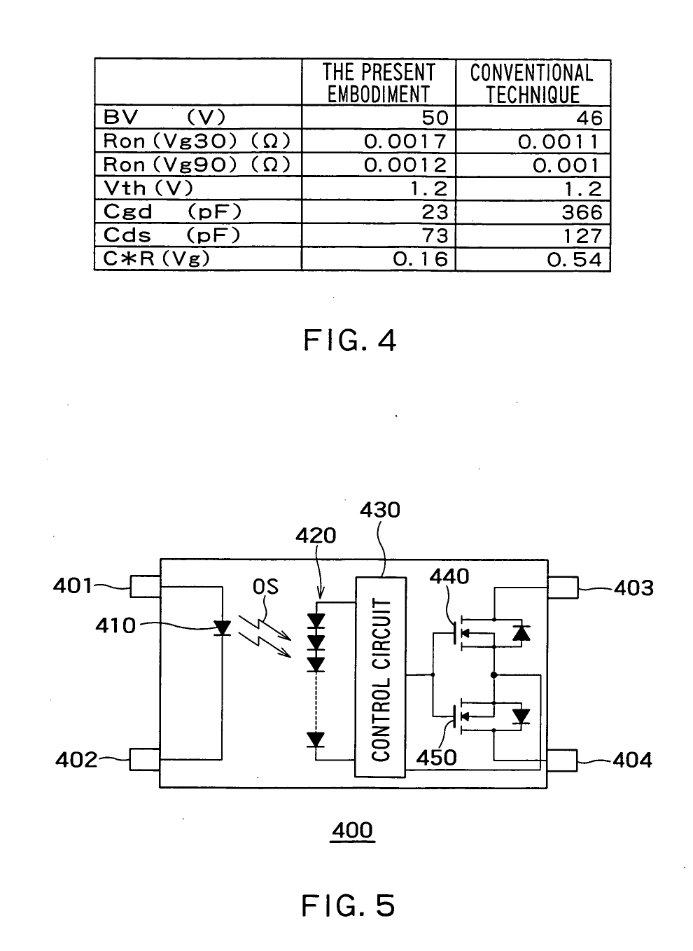

FIG. 4 is a table showing a result of carrying out a simulation of a comparison between the characteristics of the MOS 200 according to the present embodiment and the characteristics of the conventional MOS. In FIG. 4, BV denotes a break-down voltage between the source and the drain. Ron (Vg30) denotes an on-resistance when the gate voltage is 30 volts, Ron (Vg90) denotes an on-resistance when the gate voltage is 90 volts. Vth denotes a threshold voltage. Cgd and Cds denote a capacitance between the gate and the drain, and the capacitance between the source and the drain, respectively. C*R(Vg30) denotes a CR product when the gate voltage is 30 volts.

The break-down voltage BV between the source and the drain of the MOS 200 according to the present embodiment is substantially equal to or higher than that of the conventional MOS. The on-resistance of the MOS 200 is higher than that of the conventional MOS when the gate voltage is low, but is substantially equal to the on-resistance of the conventional MOS when the gate voltage is high. The capacitance Cgd between the gate and the drain of the MOS 200 and the capacitance Cds between the source and the drain of the MOS 200 decrease more than the respective capacitances of the conventional MOS, respectively. Cout (Cgd+Cds) of the MOS 200 becomes equal to or smaller than a quarter of Cout of the conventional MOS. As a result, the CR product according to the present embodiment becomes to one third or less than that of the CR product according to the conventional MOS even when the gate voltage is low.

### Fifth Embodiment

FIG. 5 is a circuit diagram of a photo relay 400 according to a fifth embodiment of the present invention. The photo relay 400 includes a light-emitting element 410, a light-receiving element string 420, a control circuit 430, a MOSFET 440 (hereinafter, “a MOS 440”), and a MOSFET 450 (hereinafter, “a MOS 450”). The light-emitting element 410 is an LED (light-emitting diode), for example. The light-receiving element string 420 is a photodiode array obtained by connecting plural LEDs in series, for example. The MOSs 440 and 450 may be any one of the MOS 100 according to the first or the second embodiment, the MOS 200 according to the third embodiment, or the MOS 300 according to the fourth embodiment.

The photo relay 400 inputs an electrical signal of a high-frequency band from terminals 401 and 402. The light-emitting element 410 converts this electrical signal into an optical signal OS. The optical signal OS is emitted to the light-receiving element string 420, which converts the optical signal OS into a direct-current photocurrent. The control circuit 430 applies a voltage based on the direct-current electricity from the light-receiving element string 420, as a gate voltage, to the MOSs 440 and 450. The MOSs 440 and 450 receive the gate voltage from the control circuit 430, and carry out a switching operation. Based on this, the photo relay 400 can amplify the power of the electrical signal from terminals 403 and 404, and output the amplified power.

The photo relay 400 according to the present embodiment includes any one of the MOSs 100 to 300, as the MOSs 440 and 450. Therefore, the photo relay 400 can be applied to not only a high-frequency signal of a few hundred MHz but also to a high-frequency signal of a few GHz in place of the mechanical relay device.

In order to increase the gate voltage of the MOSs 440 and 450, the number of light-receiving elements of the light-receiving element string 420 may be increased. With this arrangement, the on-resistance of the MOSs 440 and 450 can be further decreased.

1. A semiconductor device comprising:
a semiconductor substrate;
a semiconductor layer provided on the surface of the semiconductor substrate;
a base layer provided on the surface of the semiconductor layer;
a source layer provided on the surface of the base layer;
a trench formed to pass through the source layer, the base layer, and the semiconductor layer from the surface of the source layer, and reaching the semiconductor substrate;
a gate electrode provided from the source layer to at least the semiconductor layer within the trench; and
an insulator provided between the gate electrode and the base layer so as to fill in the inside of the trench below the gate electrode, the insulator insulating the gate electrode from the base layer, and generating a potential distribution from the gate electrode toward the semiconductor substrate when a voltage is applied to the gate electrode.

2. The semiconductor device according to claim 1, wherein the semiconductor substrate, the semiconductor layer and the source layer are first conductivity type, and the base layer is second conductivity type.

3. The semiconductor device according to claim 1, wherein the insulator consists of a dielectric material.

4. The semiconductor device according to claim 1, wherein a plural of the trenches arranged in a stripe on a surface of the source layer,
wherein in a case that Wt denotes a width of an opening of one of the trenches in the arrangement direction of the trenches and that Wp denotes a sum of the Wt and a distance between the trenches adjacent in a cross-section of the arrangement direction of the trenches,
wherein the Wp is equal to or less than twice of the Wt.

5. The semiconductor device according to claim 1, wherein a driving voltage of the gate electrode during an operation of the semiconductor device is equal to or more than a break-down voltage between the drain layer and the source layer.

6. A semiconductor device comprising:
a semiconductor substrate;
a first semiconductor layer provided on the surface of the semiconductor substrate;
a second semiconductor layer provided on the surface of the first semiconductor layer;
a base layer provided on the surface of the second semiconductor layer;
a source layer provided on the surface of the base layer;
a trench formed to pass through the source layer, the base layer, the second semiconductor layer, and the first semiconductor layer from the surface of the source layer, and reaching the semiconductor substrate;
a gate electrode provided from the source layer to at least the second semiconductor layer within the trench; and
an insulator provided between the gate electrode and the base layer so as to fill in the inside of the trench below the gate electrode and insulating the gate electrode from the base layer.

7. The semiconductor device according to claim 6, wherein the semiconductor substrate, the first semiconductor layer and the source layer are first conductivity type, and the second semiconductor layer and the base layer are second conductivity type.

8. The semiconductor device according to claim 6, wherein the semiconductor substrate and the source layer are first conductivity type, and the first semiconductor layer, the second semiconductor layer and the base layer are second conductivity type.

9. The semiconductor device according to claim 6, wherein the insulator consists of a dielectric material.

10. The semiconductor device according to claim 6, wherein a plural of the trenches arranged in a stripe on a surface of the source layer,
wherein in a case that Wt denotes a width of an opening of one of the trenches in the arrangement direction of the trenches and that Wp denotes a sum of the Wt and a distance between the trenches adjacent in a cross-section of the arrangement direction of the trenches,
wherein the Wp is equal to or less than twice of the Wt.

11. The semiconductor device according to claim 6, wherein a driving voltage of the gate electrode during an operation of the semiconductor device is equal to or more than a break-down voltage between the drain layer and the source layer.

12. A semiconductor device comprising:
a light-emitting element receiving an electrical signal, and outputting the electrical signal as an optical signal;
a photovoltaic generating element which receives an optical signal from the light-emitting element, and generates a direct-current voltage; and
a switching element including: a semiconductor substrate; a semiconductor layer provided on the surface of the semiconductor substrate; a base layer provided on the surface of the semiconductor layer; a source layer provided on the surface of the base layer; a trench formed to pass through the source layer, the base layer, and the semiconductor layer from the surface of the source layer, and reaching the semiconductor substrate; a gate electrode provided from the source layer to at least the semiconductor layer within the trench; and an insulator provided between the gate electrode and the base layer so as to fill in the inside of the trench below the gate electrode, the insulator insulating the gate electrode from the base layer, wherein
the switching element that switches the electrical signal flowing between the drain layer and the source layer, when the direct-current voltage from the photovoltaic generating element is applied to the gate electrode.

13. The semiconductor device according to claim 12, wherein the semiconductor substrate, the semiconductor layer and the source layer are first conductivity type, and the base layer is second conductivity type.

14. The semiconductor device according to claim 12, wherein the insulator consists of a dielectric material.

15. The semiconductor device according to claim 12, wherein a plural of the trenches arranged in a stripe on a surface of the source layer,
wherein in a case that Wt denotes a width of an opening of one of the trenches in the arrangement direction of the trenches and that Wp denotes a sum of the Wt and a distance between the trenches adjacent in a cross-section of the arrangement direction of the trenches,
wherein the Wp is equal to or less than twice of the Wt.

16. The semiconductor device according to claim 12, wherein a driving voltage of the gate electrode during an operation of the switching element is equal to or more than a break-down voltage between the drain layer and the source layer.

17. A semiconductor device according to claim 12, wherein the semiconductor layer including a first semiconductor layer provided on the surface of the semiconductor substrate and a second semiconductor layer provided on the surface of the first semiconductor layer,
the trench is formed to pass through the source layer, the base layer, the second semiconductor layer, and the first semiconductor layer from the surface of the source layer, and reaching the semiconductor substrate, and the gate electrode is provided from the source layer to at least the second semiconductor layer within the trench.

18. The semiconductor device according to claim 17, wherein the semiconductor substrate, the first semiconductor layer and the source layer are first conductivity type, and the second semiconductor layer and the base layer are second conductivity type.

19. The semiconductor device according to claim 17, wherein the semiconductor substrate and the source layer are first conductivity type, and the first semiconductor layer, the second semiconductor layer and the base layer are second conductivity type.

20. The semiconductor device according to claim 17, wherein the insulator consists of a dielectric material.
